(19) United States
(12) Patent Application Publication
(10) Pub. No.: US 2026/0076141 A1
(43) Pub. Date: Mar. 12, 2026

(54) SCHEDULING SUBSTRATE PROCESSING OVER MULTIPLE PROCESSING CHAMBERS

(71) Applicant: Applied Materials, Inc., Santa Clara, CA (US)

(72) Inventors: Rony David Mathew, Kollam Kerala (IN); Andreas Neuber, Feldkirchen (DE); Wei Wang, Springboro, OH (US)

(21) Appl. No.: 19/180,899

(22) Filed: Apr. 16, 2025

(30) Foreign Application Priority Data
Sep. 9, 2024 (IN) 202441067974

(51) Int. Cl. H01L 21/67

(52) U.S. Cl. CPC H10P 72/0612

(57) ABSTRACT

Technologies related to production scheduling within semiconductor fabrication plant(s) are described. Processing chambers may receive requests to complete a workload over a period of time. The workload may be scheduled across the processing chambers to maximize an aggregate time that the processing chambers are in a sleep mode.

### BACKGROUND

In the semiconductor industry and beyond, fabrication plants can have varied schedules of production that are generally optimized for faster substrate production. However, in most fabrication plants, tools are not always fully utilized due to production scheduling, which can lead to inefficient energy consumption.

### BRIEF SUMMARY

In one aspect, a method receives one or more requests to fabricate substrates. These one or more requests corresponding to a workload over a first period of time. The method schedules the workload across multiple processing chambers over the first period of time to maximize an aggregate time that the plurality of processing chambers are in a sleep mode. To do so, the method distributes, over the first period of time, the workload across the plurality of processing chambers such that the sleep mode is maximized for a first subset of the plurality of processing chambers and a production mode is maximized for a second subset of the plurality of processing chambers. The sleep mode corresponds to a lower energy consumption than the production mode.

In another aspect, a device includes one or more processors and memory storing instructions. Upon being executed, the instructions receive one or more requests to fabricate substrates. Upon being executed, the instructions schedule the workload across multiple processing chambers over the first period of time to maximize an aggregate time that the plurality of processing chambers are in a sleep mode. To do so, the instructions distribute, over the first period of time, the workload across the plurality of processing chambers such that the sleep mode is maximized for a first subset of the plurality of processing chambers and a production mode is maximized for a second subset of the plurality of processing chambers. The sleep mode corresponds to a lower energy consumption than the production mode.

In another aspect, a system includes multiple processing chambers and a device communicatively coupled to these processing chambers. The device receives one or more requests to fabricate substrates. The device schedules the workload across multiple processing chambers over the first period of time to maximize an aggregate time that the plurality of processing chambers are in a sleep mode. To do so, the device distributes, over the first period of time, the workload across the plurality of processing chambers such that the sleep mode is maximized for a first subset of the plurality of processing chambers and a production mode is maximized for a second subset of the plurality of processing chambers. The sleep mode corresponds to a lower energy consumption than the production mode.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a top schematic view of an example electronic processing system, according to one embodiment.

FIG. 2 illustrates a processing chamber network with scheduling logic, according to one embodiment.

FIG. 3A illustrates a processing chamber network with conventional production scheduling, according to one embodiment.

FIG. 3B illustrates a processing chamber network with scheduling performed by the scheduling logic as described herein, according to one embodiment.

FIG. 4A illustrates a processing schedule generated by conventional processing techniques, according to one embodiment.

FIG. 4B illustrates a processing schedule generated by the scheduling logic as described here, according to one embodiment.

FIG. 5 illustrates a method of distributing a workload among processing chambers, according to one embodiment.

FIG. 6 illustrates a method of scheduling a workload across processing chambers over a production period, according to one embodiment.

FIG. 7 is an example computing device, according to one embodiment.

### DETAILED DESCRIPTION

Technologies related to production scheduling within semiconductor fabrication plant(s) are described. Generally, scheduling for processing chambers (or other automated production tools) are optimized for faster production speeds. However, in many scenarios, these processing chambers are under-utilized; that is, in these scenarios, processing chambers are in standby mode for at least a portion of a production period. These processing chambers may be under-utilized for various reasons, one being lower production quotas over the production period. Accordingly, one or more processing chambers and/or other tools or equipment may not process substrates around the clock (e.g., 24 hours a day, 7 days a week) due to lower production requirements. Such reduced utilization of processing chambers may be in addition to tool/chamber downtime for scheduled preventative maintenance (e.g., changing of a process kit, cleaning, part replacement, etc.).

The SEMI standards have defined an energy management system based on standards E167 and E175 for managing the energy of equipment (e.g., such as processing chambers) during an idle or standby mode when substrates are not being processed. The goal of such standards is to reduce energy consumption of equipment (e.g., of processing chambers). However, there is a long recovery time to move a tool or processing chamber (e.g., one or more chamber components) that is in standby back to a full power mode to enable the processing chamber to be ready to perform substrate (e.g., wafer) processing.

While processing tools are on standby (i.e., not processing a substrate), to manage energy consumption, processing tools may be placed into a sleep mode. While processing tools are in sleep mode, less energy may be consumed than if the processing tool is in a standby mode or a production mode. However, in general, a processing tool transitioned into sleep mode can have a long recovery time before being able to transition back to production mode and can create other issues such as the first wafer effect or process transparency.

Aspects and embodiments of the present disclosure address the above problems and others by providing systems and methods that distribute workloads across processing chambers (or other automated production tools) in a manner that prioritizes sleep mode time and energy efficiency. Upon receiving a workload over a period of time, aspects and embodiments of the present disclosure may distribute the workload across the processing chambers over the period of time to maximize or otherwise prioritize an aggregate time that the processing chambers are in a sleep mode. In some embodiments, aspects and embodiments of the present disclosure may accordingly distribute the workload by distributing the workload across the processing chambers such that some of the processing chambers (e.g., first subset) each have utilization rates greater than other processing chambers (e.g., a second subset). In at least one embodiment, aspects and embodiments may maximize an amount of time that a first subset of processing chambers are in sleep mode and maximize an amount of time that a second subset of processing chambers are in production mode. By maximizing or otherwise optimizing the aggregate time that the processing chambers are in sleep mode, aspects and embodiments of the present disclosure provide systems and methods of scheduling workloads that results in greater overall production energy efficiency than conventional solutions.

Aspects and embodiments of the present disclosure provide systems and methods that reduce the first wafer effect by reducing a number of times that processing chambers transition from sleep mode to production mode. To do so, aspects and embodiments of the present disclosure may provide systems and methods that prioritize maintaining processing chambers in sleep mode during consecutive production periods where, in aggregate, the processing chambers are under-utilized.

Aspects and embodiments of the present disclosure provide systems and methods that reduce variability in processing chamber wear. To do so, aspects and embodiments of the present disclosure may provide systems and methods that, in at least some scenarios, compare relative wear between the processing chambers and prioritize sleep mode time for processing chambers with higher amounts of wear.

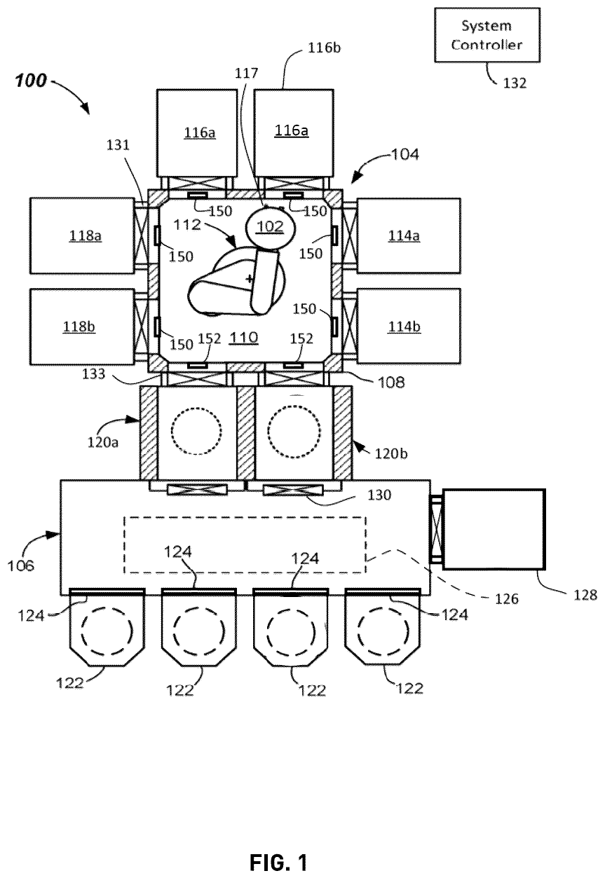

FIG. 1 is a top schematic view of an example electronics processing system 100, according to one embodiment. Electronics processing system 100 may perform one or more processes on a substrate 102. Substrate 102 may be any suitably rigid, fixed-dimension, planar article, such as, e.g., a silicon-containing disc or wafer, a patterned wafer, a glass plate, or the like, suitable for fabricating electronic devices or circuit components thereon. Electronics processing system 100 may include a mainframe 104 and a factory interface 106 coupled to mainframe 104. Mainframe 104 may include a housing 108 having a transfer chamber 110 therein. Transfer chamber 110 may include one or more processing chambers (also referred to as process chambers) 114a, 114b, 116a, 116b, 118a, 118b disposed therearound and coupled thereto. Processing chambers 114a, 114b, 116a, 116b, 118a, 118b may be coupled to transfer chamber 110 through respective ports 131, which may include slit valves or the like. Processing chambers 114a-118b may chambers for a plasma etcher or plasma etch reactor, a plasma cleaner, and so forth. In alternative embodiments other processing chambers may be used, which may or may not be exposed to a corrosive plasma environment. Some examples of chamber components include a chemical vapor deposition (CVD) chamber, a physical vapor deposition (PVD) chamber, an ion assisted deposition (IAD) chamber, an epitaxy (EPI) chamber, a chemical mechanical planarization (CMP) chamber, and other types of processing chambers. Other examples of chamber components may include atomic later deposition (ALD) components, etching components, fluorinated ethylene propylene (FEP) components, electrochemical plating (ECP) components, ion implant components, and metrology tools such as components used for surface inspection and defect analysis (e.g., Surfscan), scanning electron microscope (SEM), critical dimension SEM (CD-SEM), and bright and dark optical inspection tools. Additionally, embodiments of the present disclosure also work for ion implant chambers, photolithography systems, metrology devices, oxidation chambers, and so on. Embodiments of the present disclosure may work for any system in which there are multiple different chambers or tools that can perform the same processes on substrates, and for which a scheduler determines which of those tools/chambers to use to process a substrate at any given time.

Note that an approximately square shaped mainframe having four sides (also referred to as facets) is shown, with multiple processing chambers connected to each facet. However, it should be understood that a facet may include a single processing chamber or more than two processing chambers coupled thereto. Additionally, the mainframe 104 may have other shapes, such as a rectangular shape (in which different facets may have different lengths) or a radial shape with more than four facets (e.g., with five, six, or more facets).

Processing chambers 114a, 114b, 116a, 116b, 118a, 118b may be adapted to carry out any number of processes on substrates 102. A same or different substrate process may take place in each processing chamber 114a, 114b, 116a, 116b, 118a, 118b. A substrate process may include atomic layer deposition (ALD), physical vapordeposition (PVD), chemical vapor deposition (CVD), etching, annealing, curing, pre-cleaning, metal or metal oxide removal, or the like. In one example, a PVD process may be performed in one or both of process chambers 114a, 114b, an etching process may be performed in one or both of process chambers 116a, 116b, and an annealing process may be performed in one or both of process chambers 118a, 118b. Other processes may be carried out onsubstrates therein. Processing chambers 114a, 114b, 116a, 116b, 118a, 118b may each include a substrate support assembly. The substrate support assembly may be configured to hold a substrate in place while a substrate process is performed.

Transfer chamber 110 may also include a transfer chamber robot 112. Transfer chamber robot 112 may include one or multiple robot arms where each robot arm includes one or more end effectors 117 (also referred to herein as blades) at the end of the robot arm. The end effector 117 may be configured to handle particular objects, such as wafers. Alternatively, or additionally, the end effector 117 may be configured to handle objects such as process kit rings. In some embodiments, transfer chamber robot 112 may be a selective compliance assembly robot arm (SCARA) robot, such as a 2 link SCARA robot, a 3 link SCARA robot, a 4 link SCARA robot, and so on.

In some embodiments, ports 131 and/or slit values are at interfaces between processing chambers 114a, 114b, 116a, 116b, 118a, 118b and transfer chamber 110. Local center finders (LCFs) 150 are positioned at or proximate to each such port 131 or slit value. The local center finders 150 are each configured to determine a center of an object (e.g., a ring, wafer, substrate, etc.) passing through the associated port 131 or slit value. LCFs 150 may include an arrangement of laser and detector pairs. Each laser may project a laser beam, which may be received by a corresponding detector in a laser and detector pair. In embodiments, the lasers direct the laser beams vertically or at an angle relative to vertical. Each detector is positioned in the path of a laser beam from a corresponding laser. When an object (e.g., a calibration object, a substrate, a wafer, etc.) is passed through the port 131 or slit valve, it blocks the laser beams such that the laser beams are not received by the detectors. Based on known information about a size and shape of the calibration object or other object passing through the port 131 or slit valve, known information about positions of the lasers and detectors, and known information about respective positions of the transfer chamber robot 112 at which each of the respective detectors stopped receiving a laser beam, a center of the calibration object or other known object may be determined. Other types of LCFs may also be used, such as camera-based local center finders and/or runout ribbon-based local center finders.

One or more load locks 120a, 120b may also be coupled to housing 108 and transfer chamber 110. Load locks 120a, 120b may be configured to interface with, and be coupled to, transfer chamber 110 on one side and factory interface 106 on another side. Load locks 120a, 120b may have an environmentally-controlled atmosphere that may be changed from a vacuum environment (wherein substrates may be transferred to and from transferchamber 110) to an at or near atmospheric-pressure (e.g., with inert-gas) environment (wherein substrates may be transferred to and from factory interface 106) in some embodiments. In some embodiments, one or more load locks 120a, 120b may be a stacked load lock having one or more upper interior chambers and one or more lower interior chambers that are located at different vertical levels (e.g., one above another). In some embodiments, a pair of upper interior chambers are configured to receive processed substrates from transfer chamber 110 for removal from mainframe 104, while a pair of lower interior chambers are configured to receive substrates from factory interface 106 for processing in mainframe 104. In some embodiments, one or more load locks 120a, 120b may be configured to perform a substrate process (e.g., an etch or a pre-clean) on one or more substrates 102 received therein.

In embodiments, ports 133 and/or slit valves separate the transfer chamber 110 from the load locks 120a, 120b. LCFs 152 are positioned at or proximate to each such port 133 and/or slit value. The LCFs may be used to determine a center of objects (e.g., calibration objects, wafers, substrates, etc.) on robot arm 112 while such objects are placed in the load lock or removed from the load lock by the robot arm 112.

Factory interface (FI) 106 may be any suitable enclosure, such as, e.g., an Equipment Front End Module (EFEM). Factory interface 106 may be configured to receive substrates 102 from substrate carriers 122 (e.g., Front Opening Unified Pods (FOUPs)) docked at various load ports 124 of factory interface 106. A factory interface robot 126 (shown dotted) may be configured to transfer substrates 102 between substrate carriers (also referred to as containers) 122 and load lock 120. Factory interface robot 126 may include one or more robot arms and may be or include a SCARA robot. In some embodiments, factory interface robot 126 may have more links and/or more degrees of freedom than transfer chamber robot 112. Factory interface robot 126 may include an end effector on an end of each robot arm. The end effector may be configured to pick up and handle specific objects, such as wafers. Alternatively, or additionally, the end effector may be configured to handle objects such as process kit rings.

Any conventional robot type may be used for factory interface robot 126. Transfers may be carried out in any order or direction. Factory interface 106 may be maintained in, e.g., a slightly positive-pressure nonreactive gas environment (using, e.g., nitrogen as the nonreactive gas) in some embodiments.

In some embodiments, a side storage pod (SSP, not shown) is coupled to the FI 106.

The substrate carriers 122 as well as load ports 124, substrate carriers 122, load locks 120a, 120b, SSPs, and processing chambers 114a, 114b, 116a, 116b, 118a, 118b are each considered to be or include stations herein. Another type of station is an aligner station 128. In some embodiments, transfer chamber 110, process chambers 114a, 114b, 116a, 116b, and 118a, 118b, and load lock 120 may be maintained at a vacuum level. Electronics processing system 100 may include one or more ports 130, 131, 133 (e.g., vacuum ports) that are coupled to one or more stations of electronics processing system 100. For example, ports 130 (e.g., vacuum ports) may couple factory interface 106 to load locks 120. Additional ports 133 (e.g., vacuum ports) may be coupled to load locks 120 and disposed between load locks 120 and transfer chamber 110, as discussed above. Each of the ports 130, 133, 131 may include slit valves that separate a vacuum environment from a higher pressure (e.g., atmospheric pressure) environment.

In some embodiments, an aligner station 128 is coupled to FI 106. Alternatively, aligner station 128 may be housed in FI 106. A port separates aligner station 128 from the FI 106 in some embodiments. Aligner station 128 is configured to align substrates, fixtures, and/or other objects (e.g., process kit rings) to a target orientation. Aligner station 128 includes a substrate support onto which an object can be placed. Once an object is placed on the substrate support, the substrate support and object placed thereon are rotated, and an initial orientation on the aligner station and a target orientation on the aligner station may be detected based on such orientation.

In one embodiment, the aligner station 128 includes one or more pairs of lasers and detectors (e.g., a line of laser and detector pairs). The laser(s) may each project a laser beam that is vertical or at an angle to vertical. Each detector may be in a path of a laser beam, and detects the laser beam when the laser beam is received by the detector. As the supported object (e.g., a calibration object, a substrate, a wafer, etc.) is rotated, one or more of the laser beams is interrupted by the object such that it is not received by a detector for each rotation setting. This information may be used to determine a distance between an edge of the object at a particular location that interrupted the one or more laser beams and a center of the aligner station for each rotation setting of the aligner station. Each object includes a fiducial such as a flat, a notch, a projection, etc. that can be detected by the aligner station. For example, as the object is rotated, the distance between the edge of the object and the center of the aligner station may be determined for each rotation setting, and a known shape of the fiducial may be used to identify the fiducial in the object from the determined distances. Once the rotation setting associated with the fiducial location is identified, the phase of the object can be determined. This information can be used to determine a target orientation of the object as well as an initial orientation that the object had when it was placed at the aligner station 128. Additionally, aligner station 128 may detect runout of a circular object placed off center from a center of the aligner station based on the detected phase of the object and the distances between the edge of the object and the center of the aligner station for each rotation setting. Other detection mechanisms may also be used to detect orientation and/or runout of objects at the aligner station.

Electronics processing system 100 may also include a system controller 132. System controller 132 may be and/or include a computing device such as a personal computer, a server computer, a programmable logic controller (PLC), a microcontroller, and so on. System controller 132 may include one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. System controller 132 may include a data storage device (e.g., one or more disk drives and/or solid-state drives), a main memory, a static memory, a network interface, and/or other components. System controller 132 may execute instructions to perform any one or more of the methodologies and/or embodiments described herein. The instructions may be stored on a computer readable storage medium, which may include the main memory, static memory, secondary storage and/or processing device (during execution of the instructions). System controller 132 may also be configured to permit entry and display of data, operating commands, and the like by a human operator.

In some embodiments, system controller 132 causes electronics processing system 100 to perform one or more calibration procedures to generate calibration data (e.g., characteristic error values) associated with one or more stations, one or more robots and/or one or more wafer transfer sequences. System controller 132 stores the calibration values (e.g., characteristic error values) in one or more data storage devices. System controller 132 later uses appropriate calibration values when instructing the aligner station 128 to align an object, when instructing the FI robot 126 to retrieve or place an object and/or when instructing the transfer chamber robot 112 to retrieve or place an object.

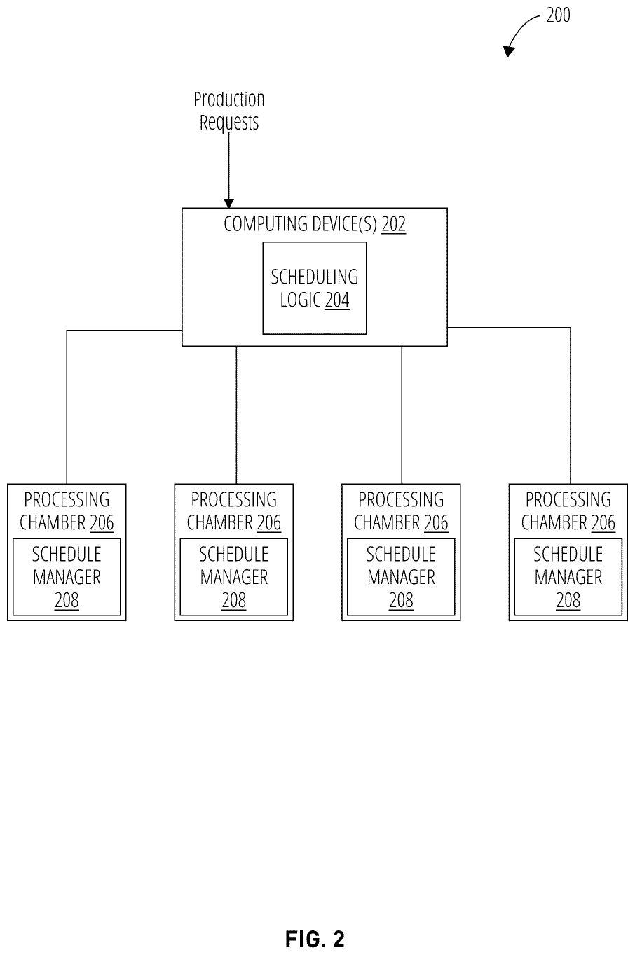

FIG. 2 illustrates a processing chamber network 200 (e.g., a multi-tool system such as a plurality of processing chambers 206 coupled to a transfer chamber) with scheduling logic, according to one embodiment. In one embodiment, processing chambers 206 correspond to processing chambers 114a-118b of FIG. 1. The processing chamber network 200 may include one or more computing device(s) 202 that are communicatively coupled to processing chambers 100.

In one embodiment, the computing device(s) 202 may be a cloud computing device(s) (e.g., one or more servers that execute on virtual machines) that communicate scheduling information to the processing chambers 206 via the a network such as the Internet, a private wide area network (WAN) such as an intranet, and so on. In some embodiments, the computing devise 202 are local server computing devices at a fabrication facility (Fab) that communicate with the processing chambers 206 via a local area network (LAN). In some embodiments, computing device(s) 202 communicate with processing chambers wirelessly or via a wired connection. In some embodiments, computing device(s) 202 correspond to a controller for a manufacturing system, such as controller 132 of FIG. 1. In some embodiments, the computing device(s) 202 may wirelessly communicate with the processing chambers 206 using one or more wireless technologies, such as radio frequency (RF) communication (e.g., Wi-Fi®, Bluetooth®, low energy Bluetooth® (BLE®), ZigBee®, or other local or personal area networks), wide area networks, or the like. In at least one embodiment, some or all of the computing device(s) 202 may be physically coupled to the processing chambers 206. In other words, the computing device(s) 202 and processing chambers 206 may operatively connected in some form such that scheduling information generated by the computing device(s) 202 is capable of reaching the processing chambers 206.

The processing chambers 206 may have some or all of the features of the processing chambers 114a-118b as described above with respect to FIG. 1. While the processing chamber network 200 is illustrated as having four processing chambers 206, the processing chamber network 200 may have any number of processing chambers 206. According to embodiments, the processing chamber network 200 may have at least two processing chambers 206. These processing chambers 206 may be connected to a same mainframe (also referred to as processing tool or cluster platform) or may be connected to different mainframes within a same production plant. In at least one embodiment, these processing chambers 206 may be part of different fabrication plants. In other words, the systems and methods of the present disclosure may be utilized to generate distribution schedules for any number of processing chambers 206 connected to one or more mainframes or located within one or more fabrication plants.

Each processing chamber 206 may have a schedule manager 208. These schedule managers 208 may each be executed by a controller (or other computing device) that manages the operations of the respective processing chambers 206. This controller may be internal or external to each of the processing chambers 206. In various embodiments, this controller may be the controller 132 as described above with respect to FIG. 1. In one embodiment, this controller is a different controller than the controller 132. In some embodiments, schedule managers 208 of some or all of the processing chambers 206 may be executed by a controller that manages the operations of these processing chambers 206. In at least one of these embodiments, a single schedule manager 208 may be configured to manage these processing chambers 206 via a shared controller.

According to embodiments, the schedule manager 208 may manage a mode of one or more processing chambers 206. A processing chamber 206 may be in one of at least three modes: a production mode, a standby mode, or a sleep mode. In some embodiments, the processing chamber 206 may also be in other modes. In at least one embodiment, the production and standby modes may be considered a same mode; for example, the production mode may refer to a time where the processing chamber 206 is actively processing substrates, while the standby mode may refer to a time where the processing chamber 206 is not actively processing substrates, but maintains a readiness to process substrates. Accordingly, the production and standby modes may each be aspects of an active or high power mode.

The schedule manager(s) 208 use scheduling information received from the computing device(s) 202 to manage scheduling of substrates on the one or more processing chambers 206. In at least one embodiment, the computing device(s) 202 may periodically send distribution schedules to the schedule manager(s) 208 that correspond to different production periods. As used herein, a production period may refer to a period of time for which a distribution schedule is processed. This distribution schedule may include information about when the one or more processing chambers are in a production, standby, or sleep mode. This distribution schedule may also include other information, including but not limited to how many substrates to process while in production mode, what recipe to use to process the substrates, and/or a period of time reserved for priority substrate production.

As used herein, the production mode refers to a mode and/or time where the processing chamber 206 is actively processing substrate(s). This production mode is generally associated with a higher energy consumption than the standby and sleep modes. The standby mode refers to a mode and/or time where the processing chamber 206 is not actively processing substrate(s) but is also not in sleep mode. This standby mode is generally associated with a lower energy consumption than production mode, but a higher energy consumption than sleep mode. The sleep mode may refer to a mode and/or time where one or more parameters of the processing chamber 206 have been adjusted to lower energy consumption. These adjustments may include, but are not limited to: reducing or stopping pressure regulation within the processing chamber 206; reducing or stopping temperature regulation within the processing chamber 206; reducing or stopping operations of cooling systems of the processing chamber 206; reducing or stopping purging operations of the processing chamber 206; and/or lowering power operating states of electrical systems part of the processing chamber 206. This sleep mode is generally associated with a lower energy consumption than the production and standby modes.

According to embodiments, a processing chamber 206 in sleep mode may be unable to immediately transition to production mode or idle mode because, due to the parameters adjusted to lower energy operating modes, the processing chamber 206 is not ready to immediately process substrates. The time that the processing chamber 206 spends in sleep mode can cause pressure instability, internal temperature drift, contamination risk, or the like. Additionally, systems brought to a lower (or stopped) operational status during sleep mode may have a reboot period, such as of the cooling system and/or electrical system of the processing chamber 206. In other words, changes made during sleep mode affect the readiness of the processing chamber 206, and a minimum recovery time may pass before the processing chamber 206 is again ready to process substrates in production mode after transitioning out of sleep mode. During this recovery time, the processing chamber 206 adjusts its systems and parameters back to higher energy operating states, which restores the readiness of the processing chamber 206 to process substrates. So, in at least one embodiment, for a processing chamber 206 that is in sleep mode during a production period, a distribution schedule for the processing chamber 206 has a period of time greater than the minimum recovery time where the processing chamber 206 is not in production mode (e.g., is not scheduled to process substrates). As such, this minimum recovery time may be associated with a minimum cycle duration of the sleep mode for the processing chamber 206. This minimum cycle duration may be dependent on several different factors, including but not limited to the type or size of the processing chamber 206, parameters or specifications of components or systems of the processing chamber 206, the recipe to be used by the processing chamber 206 to process substrates, safety checks, and/or other external factors.

The computing device(s) 202 may include scheduling logic 204. The computing device(s) 202 may include memory to store instructions that, upon execution, causes the computing device(s) 202 to perform the operations of the scheduling logic 204. In one embodiment, operations of the scheduling logic 204 may be distributed among multiple computing devices 202. In another embodiment, each of the computing device(s) 202 may perform some or all of the operations of the scheduling logic 204. According to embodiments, the scheduling logic 204 may be configured to generate distribution schedules based on one or more received production requests. These production requests may include information including, but not limited to, a number of substrates to be processed according to the request, a recipe to be used to process these substrates, a timestamp denoting a time the request was received, and/or a deadline by which the request is to be fulfilled. Each production request received may have a corresponding workload. This workload may refer to a total amount of processing tasks or operations that are to be completed. In some embodiments, a workload may be measured in terms of production time. This production time may refer to how long a processing chamber takes to complete the workload corresponding to the production request. In at least one embodiment, the workload may also be measured in terms of utilization rate. For example, if a processing chamber 206 will take 30 minutes of a 60-minute production period to complete a workload, the workload would have a utilization rate of 50%.

In a scenario where the computing device(s) 202 is to receive multiple production requests that are to be completed within a production period by the processing chamber(s) 206, the scheduling logic 204 may compare an aggregate workload corresponding to these production requests to an aggregate utilization capacity of the processing chambers 206. For example, if the processing chamber network 200 operates on a five (5) hour production period (300 minutes), and the processing chamber network 200 has four operational processing chambers 206, the processing chamber network 200 may have a utilization capacity of 20 hours (1,200 minutes). If the aggregate workload is 15 hours (900 minutes), the aggregate workload would have an aggregated utilization rate of 75%.

While the above example uses time and utilization rate to measure workload, one of skill in the art will appreciate that various other approaches to measuring workload may be used, such as comparing number of substrates to processing chamber throughput (e.g., products per hour (PPH), or wafers per hour (WPH)) or the like.

According to embodiments, the scheduling logic 204 may be configured to maximize or otherwise optimize an amount of time that the processing chambers 206 are in sleep mode. As explained above, in order for a processing chamber 206 to be in sleep mode, the distribution schedule for the processing chamber 206 should have a period of time without active substrate production that is equal to or larger than the minimum cycle duration of the sleep mode. This minimum cycle duration may be measured as a percentage of a utilization capacity of the processing chamber 206. The utilization capacity percentage of the minimum sleep mode cycle duration may be application specific. For example, using a first recipe, the minimum sleep mode cycle duration may be approximately 15 minutes. Here, if the production period is one (1) hour (60 minutes), the utilization capacity percentage of the minimum sleep mode cycle duration would be 25%, while if the production period is two (2) hours (120 minutes), the utilization capacity percentage of the minimum sleep mode cycle duration would be 12.5%. However, using an exemplary second recipe, the minimum sleep mode cycle duration may approximately 10 minutes, which would have a different utilization capacity percentage than the first recipe.

According to embodiments, during some production periods, the aggregate workload may be so large that no individual processing chamber 206 could enter sleep mode. To determine this, the scheduling logic 204 may compare utilization capacity percentage(s) of recipe(s) of the corresponding production requests against a remaining aggregate utilization capacity of the processing chamber network 200 after accounting for the aggregate workload utilization rate. If the utilization capacity percentage(s) of recipe(s) are larger than the remaining aggregate utilization capacity, the scheduling logic 204 may conclude that the processing chamber network 200 is not under-utilized and may generate distribution schedule(s) for the processing chambers 206 that maximizes or prioritizes something other than aggregate sleep mode time of the processing chambers 206 (e.g., faster substrate production, avoid switching recipes on a processing chamber 206, or the like).

For other production periods, the aggregate workload may be small enough that one or more processing chambers 206 may be in sleep mode during the corresponding production period. The scheduling logic 204 may determine this by determining that at least one of the utilization capacity percentage(s) of recipe(s) is smaller than the remaining aggregate capacity percentage described above. This may indicate that, in at least some cases, workloads of the production requests may be arranged by the scheduling logic 204 such that at least one of the processing chambers 206 has a period of time without processing substrates larger than the minimum sleep mode cycle duration. The scheduling logic 204 may generate distribution schedule(s) for the corresponding production period to maximize or otherwise prioritize the aggregate time that the processing chambers 206 are in sleep mode.

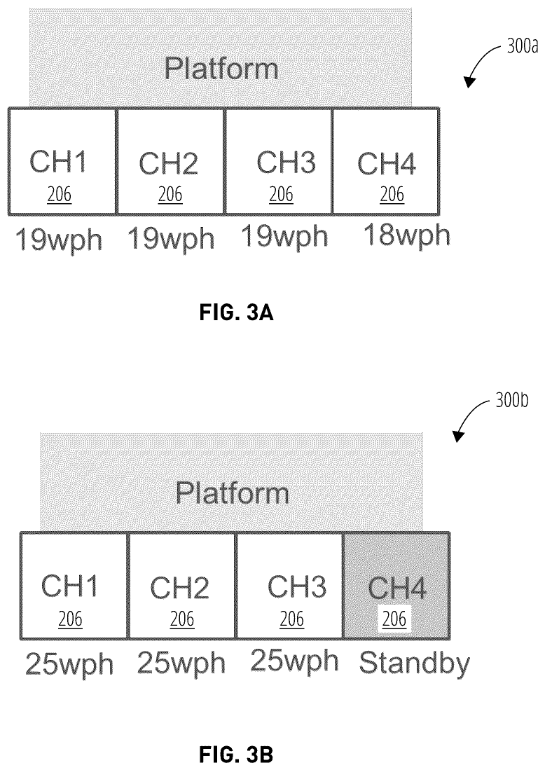

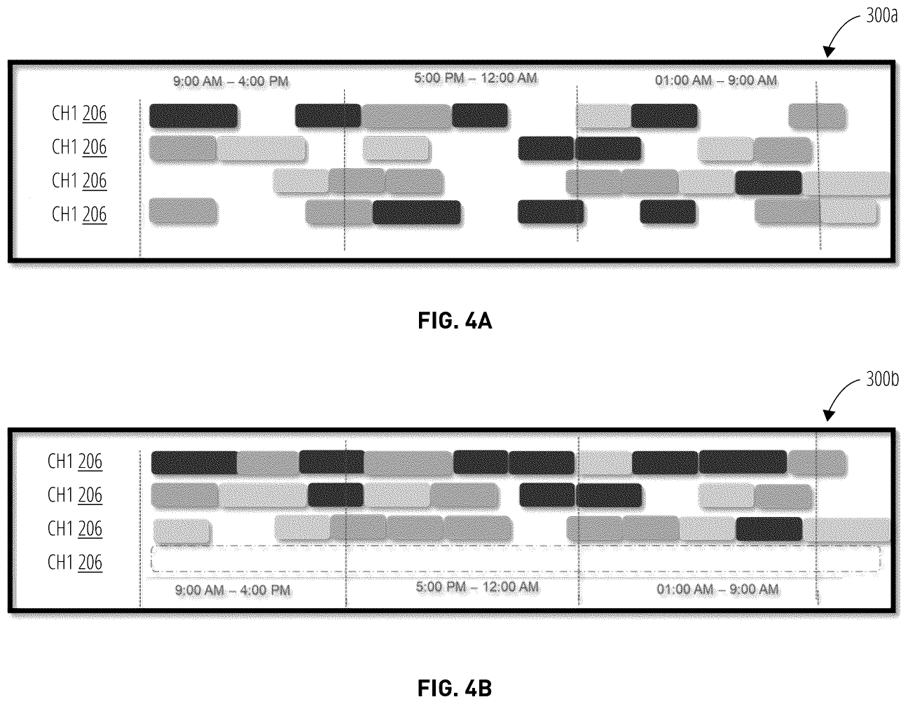

FIG. 3A and FIG. 3B can provide an example of how the scheduling logic 204 may maximize or optimize aggregate time spent by processing chambers 206 in sleep mode. FIG. 3A illustrates the processing chamber network 200 with conventional distribution scheduling 300a, according to one embodiment. FIG. 3B illustrates the processing chamber network 200 with distribution scheduling 300b performed by the scheduling logic 204 as described herein, according to one embodiment. FIG. 4A and FIG. 4B are also illustrated to provide an additional example to conventional distribution scheduling 300a and distribution scheduling 300b performed by the scheduling logic 204.

Consider a scenario where the processing chamber network 200 has four processing chambers 206 (CH1-CH4) that each have a throughput rate of 25 wafers per hour (WPH). Here, the aggregate throughput rate would be 100 WPH. In the example illustrated in FIGS. 3A-4B, a production period has a corresponding workload of 75 wafers to be completed. So, this workload has a utilization rate of 75% of the total utilization capacity of the processing chambers 206. Under conventional distribution scheduling 300a, the production of these 75 wafers may be distributed among the four processing chambers 206 as illustrated in FIG. 3A and FIG. 4A. Thus, according to the conventional distribution scheduling 300a, these processing chambers 206 would have individual utilization rates of approximately 75%. In at least some embodiments (e.g., in this example, when the minimum sleep mode cycle duration would be greater than 25% of the individual utilization capacities of the processing chambers 206), these processing chambers would not have time to enter sleep mode because too much of the production period is dedicated to processing wafers. In these embodiments, the processing chambers 206 may transition between production mode and standby mode, but may not be able to enter sleep mode.

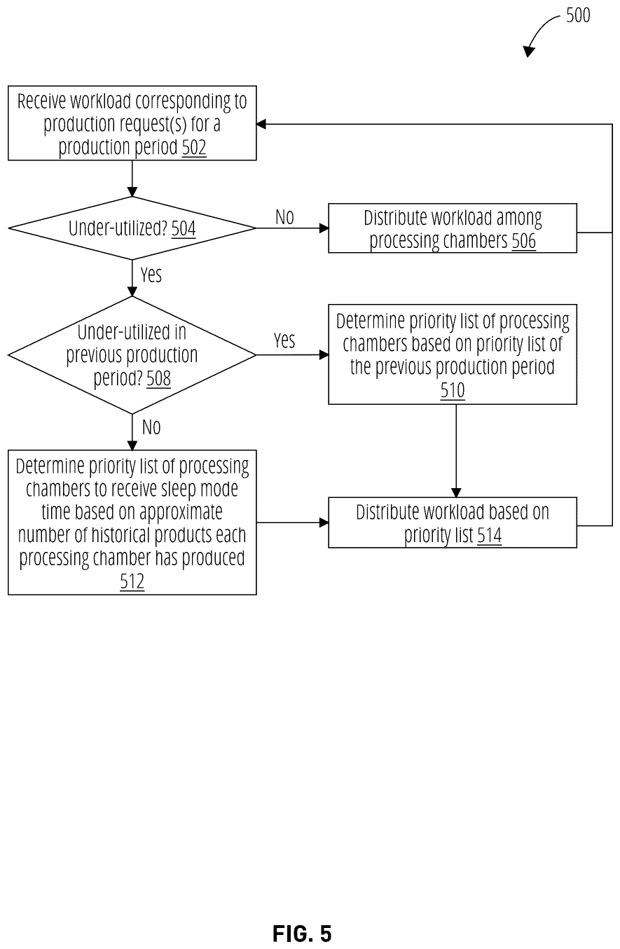

Conversely, under distribution scheduling 300b performed by the scheduling logic 204 as described herein, the production of these 75 wafers may be distributed to maximize or optimize an aggregate amount of time the processing chambers 206 are in sleep mode. In at least one embodiment, the scheduling logic 204 may achieve as close to the remaining aggregate utilization capacity as possible, considering that, in at least some embodiments, workloads of different production requests may vary and 100% utilization of processing chambers 206 may be unlikely. In other embodiments, a portion of the aggregate utilization capacity may be reserved for overflow or priority substrate production. FIG. 3B and FIG. 4B illustrate an example distribution of the workload, where three of the processing chambers 206 (CH1-CH3) are scheduled at 100% utilization (or near 100% utilization) and the fourth processing chamber 206 (CH4) is scheduled at a 0% utilization. This scheduling effectively maximizes the aggregate amount of time that the processing chambers 206 are in sleep mode. According to embodiments, the scheduling logic 204 may prioritize which of the processing chambers 206 should be in sleep mode during the production period, which is described herein at least in FIG. 5. While FIG. 3B and FIG. 4B illustrate one possible distribution scheduling to maximize or optimize the aggregate amount of time the processing chambers 206 are in sleep mode during the production period, many other distribution schedules are possible as well. For example, as long as the minimum sleep mode cycle duration is less than or equal to 50% of the individual utilization capacity of the processing chambers 206, the scheduling logic 204 may have scheduled the first two chambers (CH1-CH2) at 100% utilization and the last two chambers (CH3-CH4) at 50% utilization.

In embodiments, rather than selecting a least utilized processing chamber to process a substrate at any given time (e.g., as in a standard scheduling system), processing logic may continue to schedule substrates to be processed to a single processing chamber until utilization of the processing chamber is full (optionally with a buffer). Once the utilization of that processing chamber is full, processing logic may begin scheduling substrates for a next processing chamber until that processing chamber is full, and so on. In this manner, if the system as a whole (including all of the processing chambers) is underutilized, then one or more of the processing chambers may have a large amount of idle time, and may transition to sleep mode for an increased percentage of time as compared to traditional scheduling, reducing overall energy consumption of the system.

FIG. 5 illustrates a method 500 of distributing a workload among processing chambers, according to one embodiment. The method 500 may be performed by processing logic that may comprise hardware (e.g., circuitry, dedicated logic, programmable logic, microcode, etc.), software (e.g., instructions run on a processing device to perform hardware simulation), firmware, or a combination thereof. In at least one embodiment, the processing logic may refer to one or more components of a larger system, such as a processing chamber network (e.g., processing chamber network 200). These components may include one or more processors and a memory storing instructions that, when executed by the one or more processors (or computing device(s) 202), perform the method 500. One or more operations of the method 500 may correspond to operations of the scheduling logic 204, as described herein. The method 500 can be performed at least partially by other devices described herein.

At block 502, the processing logic may receive a workload corresponding to one or more production requests. These production requests may correspond to a production period. In at least one embodiment, this received workload is to be completed by processing chambers (e.g., processing chambers 206) that are part of a processing chamber network (e.g., that are connected to a same transfer chamber in some embodiments). The workload may be completed within the production period.

At decision block 504, the processing logic may determine whether the processing chambers are under-utilized over the production period. The processing chambers may be under-utilized if, depending on how the workload is scheduled over the production period, at least one processing chamber can enter sleep mode. In other words, the processing chambers may be under-utilized if, depending on how the workload is scheduled over the production period, at least one processing chamber can have an amount of time without active substrate production that is greater than the minimum sleep mode cycle duration. In some embodiments, the processing logic may determine whether the processing chambers are under-utilized by comparing an aggregated utilization capacity of the processing chambers to an aggregated utilization rate of the workload. This comparison may be performed as described herein. If the processing logic determines that the processing chambers are under-utilized over the production period, the method 500 may move to decision block 508. If the processing logic determines that the processing chambers are not under-utilized over the production period, the method 500 may move to block 506 where the processing logic distributes the workload among the processing chambers over the production period using conventional approaches or techniques.

At decision block 508, the processing logic may determine whether the processing chambers were under-utilized during a previous production period. This previous production period may be directly preceding the production period to which the workload corresponds. If the processing chambers were under-utilized during the previous production period, the method 500 may move to block 510. If the processing chambers were not under-utilized during the previous production period, the method 500 may move to block 512.

At block 510, the processing logic may determine a priority list of the processing chambers based on a previous priority list generated for the previous production period. This priority list may be represented in any suitable form where one processing chamber is given priority to enter sleep mode during the production period over a different processing chamber. By determining the priority list based on the previous priority list, chambers that are in sleep mode entering the production period may continue to stay in sleep mode, which reduces transitions between production and sleep mode and reduces instances of the first wafer effect.

At block 512, the processing logic may determine the priority list such that each of the processing chambers processes approximately a same number of substrates over a period of time encompassing the production period and historical production period(s) (e.g., a second period of time). In some embodiments, the processing logic determines the priority list based on an approximate number of historical substrates each processing chamber has processed over a historical period of time. This historical period of time may span over multiple historical production periods. The processing logic may approximate or precisely measure how many substrates each processing chamber has processed in many different ways. For example, the processing logic may maintain a counter that measures how many substrates each processing chamber has processed. In another example, the processing logic may maintain values that indicate how long each processing chamber has been in sleep mode. In another example, the processing logic may measure how long each processing chamber has been in production mode. Notwithstanding these examples, any approach or technique to approximating or otherwise measuring how many substrates each processing chamber has processes may be used by the processing logic to perform the operations of block 512. In embodiments, the processing chambers may be assigned priority ratings such that a processing chamber that has been in sleep mode the least and/or that has processed the most substrates is prioritized for sleep mode and a processing chamber that has been in sleep mode the most and/or that has processed the least number of substrates is prioritized for processing substrates. The processing chamber(s) that are prioritized for processing substrates may have their queues filled before one or more next processing chambers are scheduled for processing substrates. In this manner, the wear rate across the multiple processing chambers may be approximately even.

At block 514, the processing logic may distribute the workload based on the priority list. To do so, the processing logic may generate a distribution schedule that is then used by the processing chambers to complete the workload and, according to the distribution schedule, transition into sleep mode. For example, a processing chamber having a rating of 1 may have its schedule filled, after which a processing chamber having a rating of 2 may have its schedule filled, and so on until all substrates of a workload have been scheduled. If the system is underutilized, then this leaves one or more of the lower rated processing chambers for that cycle to have accumulated idle periods, enabling them to enter a sleep mode for a maximum possible amount of time for the given workload.

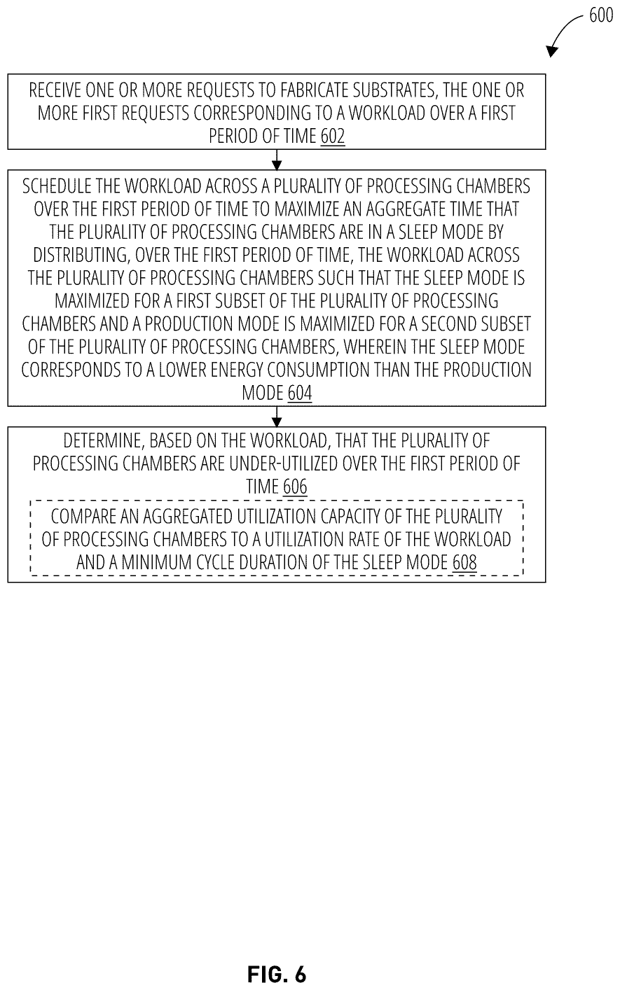

FIG. 6 illustrates a method 600 of scheduling a workload across processing chambers over a production period (e.g., first period of time), according to one embodiment. The method 600 may be performed by processing logic that may comprise hardware (e.g., circuitry, dedicated logic, programmable logic, microcode, etc.), software (e.g., instructions run on a processing device to perform hardware simulation), firmware, or a combination thereof. In at least one embodiment, the processing logic may refer to one or more components of a larger system, such as a processing chamber network (e.g., processing chamber network 200). These components may include one or more processors and a memory storing instructions that, when executed by the one or more processors (or computing device(s) 202), perform the method 600. One or more operations of the method 600 may correspond to operations of the scheduling logic 204, as described herein. The method 600 can be performed at least partially by other devices described herein.

At block 602, the processing logic may receive one or more requests to fabricate substrates, the one or more requests corresponding to a workload over a first period of time.

At block 604, the processing logic may schedule the workload across multiple processing chambers over the first period of time. The processing logic may schedule the workload in order to maximize an aggregate time that the processing chambers are in a sleep mode. The processing logic may maximize this aggregate time by distributing the workload across the processing chambers such that the sleep mode is maximized for a first subset of the processing chambers and a production mode is maximized for a second subset of the processing chambers. In at least one embodiment, the sleep mode corresponds to a lower energy consumption than the production mode.

At block 606, the processing logic may determine that the processing chambers are under-utilized over the first period of time. The processing logic may determine that the processing chambers are under-utilized based on the workload. Optionally, as seen in block 608, to determine that the processing chambers are under-utilized, the processing logic may compare an aggregated utilization capacity of the processing chambers to (i) a utilization rate of the workload and (ii) a minimum cycle duration of the sleep mode.

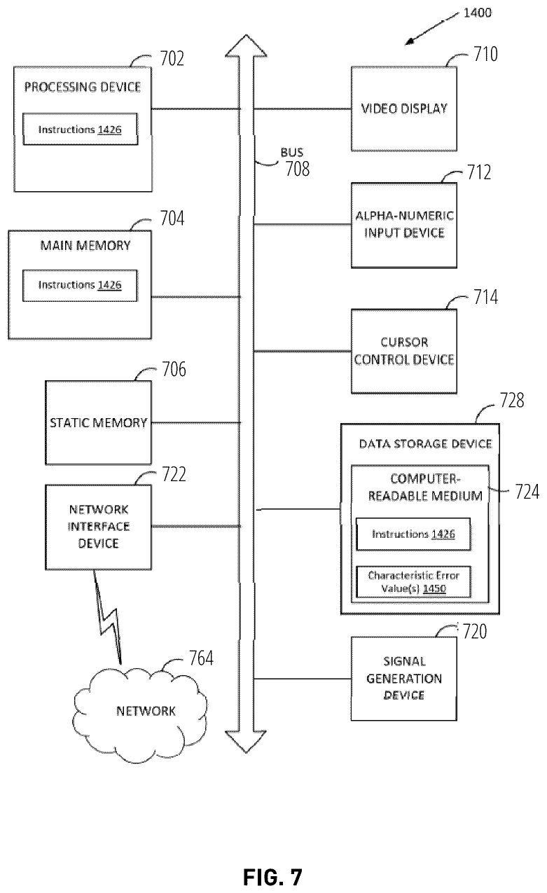

FIG. 7 is an example computing device 700, according to one embodiment. The computing device 700 is a machine within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In an embodiment, computing device 700 corresponds to system controller 132 of FIG. 1. In one embodiment, system controller 132 is a component of computing device 700.

The example computing device 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory (e.g., a data storage device 712), which communicate with each other via a bus 708.

Processing device 702 represents one or more general-purpose processors such as a microprocessor, central processing unit, or the like. More particularly, the processing device 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 702 may also be one or more special-purpose processing devices such as an application specific integrated circuit (ASIC), a field programmable gate array (FPGA), a digital signal processor (DSP), network processor, or the like. Processing device 702 is configured to execute the processing logic (instructions 722) for performing the operations discussed herein. In one embodiment, system controller 132 corresponds to processing device 702. In embodiments, processing device 702 executes instructions 726 to implement any of methods 600-1300 in embodiments.

The computing device 700 may further include a network interface device 708. The computing device 700 also may include a video display unit 710 (e.g., a liquid crystal display (LCD) or a cathode ray tube (CRT)), an alphanumeric input device 712 (e.g., a keyboard), a cursor control device 714 (e.g., a mouse), and a signal generation device 716 (e.g., a speaker).

The data storage device 718 may include a machine-readable storage medium (or more specifically a computer-readable storage medium) 728 on which is stored one or more sets of instructions 722 embodying any one or more of the methodologies or functions described herein. The instructions 722 may also reside, completely or at least partially, within the main memory 704 and/or within the processing device 702 during execution thereof by the computer system 700, the main memory 704 and the processing device 702 also constituting computer-readable storage media.

The computer-readable storage medium 728 may also be used to store instructions 726 and/or characteristic error values 750 as discussed herein above. While the computer-readable storage medium 728 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium other than a carrier wave that is capable of storing or encoding a set of instructions for execution by the machine and that cause the machine to perform any one or more of the methodologies described herein. The term “computer-readable storage medium” shall accordingly be taken to include, but not be limited to, the non-transitory media including solid-state memories, and optical and magnetic media.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present invention. Thus, the specific details set forth are merely exemplary. Particular embodiments may vary from these exemplary details and still be contemplated to be within the scope of the present disclosure.

Reference throughout this specification to “one embodiment” or “an embodiment” indicates that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or. ” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of embodiments of the invention should, therefore, be determined with reference to the appended claims, along with the full scope of equivalents to which such claims are entitled.

What is claimed is:

1. A method comprising:
receiving one or more requests to fabricate substrates, the one or more requests corresponding to a workload over a first period of time; and
scheduling the workload across a plurality of processing chambers over the first period of time to maximize an aggregate time that the plurality of processing chambers are in a sleep mode by distributing, over the first period of time, the workload across the plurality of processing chambers such that the sleep mode is maximized for a first subset of the plurality of processing chambers and a production mode is maximized for a second subset of the plurality of processing chambers, wherein the sleep mode corresponds to a lower energy consumption than the production mode.

2. The method of claim 1, further comprising:
determining, based on the workload, that the plurality of processing chambers are under-utilized over the first period of time.

3. The method of claim 2, wherein determining that the plurality of processing chambers are under-utilized comprises:
comparing an aggregated utilization capacity of the plurality of processing chambers to a utilization rate of the workload and a minimum cycle duration of the sleep mode.

4. The method of claim 1, further comprising:
determining a priority list corresponding to the plurality of processing chambers such that, over a second period of time comprising the first period of time, each of the plurality of processing chambers processes approximately a same number of substrates.

5. The method of claim 4, wherein the priority list is based on an amount of time each of the plurality of processing chambers is in sleep mode within the second period of time.

6. The method of claim 4, wherein the priority list is based on a previous priority list corresponding to a second period of time preceding the first period of time.

7. The method of claim 1, wherein a first processing chamber of the plurality of processing chambers is connected to a first mainframe and a second processing chamber of the plurality of processing chambers is connected to a second mainframe that is different from the first mainframe.

8. A device comprising:
one or more processors; and
a memory storing instructions that, upon being executed by the one or more processors, configure the device to:
receive one or more requests to fabricate substrates, the one or more requests corresponding to a workload over a first period of time; and
schedule the workload across a plurality of processing chambers over the first period of time to maximize an aggregate time that the plurality of processing chambers are in a sleep mode by distributing, over the first period of time, the workload across the plurality of processing chambers such that the sleep mode is maximized for a first subset of the plurality of processing chambers and a production mode is maximized for a second subset of the plurality of processing chambers, wherein the sleep mode corresponds to a lower energy consumption than the production mode.

9. The device of claim 8, wherein the instructions further configure the device to:
determine, based on the workload, that the plurality of processing chambers are under-utilized over the first period of time.

10. The device of claim 9, wherein to determine that the plurality of processing chambers are under-utilized, the instructions configure the device to:
compare an aggregated utilization capacity of the plurality of processing chambers to a utilization rate of the workload and a minimum cycle duration of the sleep mode.

11. The device of claim 8, wherein the instructions further configure the device to:
determine a priority list corresponding to the plurality of processing chambers such that, over a second period of time comprising the first period of time, each of the plurality of processing chambers processes approximately a same number of substrates.

12. The device of claim 11, wherein the priority list is based on an amount of time each of the plurality of processing chambers is in sleep mode within the second period of time.

13. The device of claim 11, wherein the priority list is based on a previous priority list corresponding to a second period of time preceding the first period of time.

14. The device of claim 8, wherein a first processing chamber of the plurality of processing chambers is connected to a first mainframe and a second processing chamber of the plurality of processing chambers is connected to a second mainframe that is different from the first mainframe.

15. A system comprising:
a plurality of processing chambers; and
one or more devices communicatively coupled to the plurality of processing chambers, wherein the one or more devices are to:
receive one or more requests to fabricate substrates, the one or more requests corresponding to a workload over a first period of time; and
schedule the workload across the plurality of processing chambers over the first period of time to maximize an aggregate time that the plurality of processing chambers are in a sleep mode by distributing, over the first period of time, the workload across the plurality of processing chambers such that the sleep mode is maximized for a first subset of the plurality of processing chambers and a production mode is maximized for a second subset of the plurality of processing chambers, wherein the sleep mode corresponds to a lower energy consumption than the production mode.

16. The system of claim 15, wherein the one or more devices are further to:
determine, based on the workload, that the plurality of processing chambers are under-utilized over the first period of time.

17. The system of claim 16, wherein to determine that the plurality of processing chambers are under-utilized, the one or more devices are to:
compare an aggregated utilization capacity of the plurality of processing chambers to a utilization rate of the workload and a minimum cycle duration of the sleep mode.

18. The system of claim 15, wherein the one or more devices are further to:
determine a priority list corresponding to the plurality of processing chambers such that, over a second period of time comprising the first period of time, each of the plurality of processing chambers processes approximately a same number of substrates.

19. The system of claim 18, wherein the priority list is based on an amount of time each of the plurality of processing chambers is in sleep mode within the second period of time.

20. The system of claim 15, wherein a first processing chamber of the plurality of processing chambers is connected to a first mainframe and a second processing chamber of the plurality of processing chambers is connected to a second mainframe that is different from the first mainframe.
